(19) United States
(12) Patent Application Publication
(10) Pub. No.: US 2010/0182483 A1
(43) Pub. Date: Jul. 22, 2010

(54) Manufacturing Method Of Imaging Device, Imaging Device, and Mobile Terminal

(76) Inventor: Masanao Majima, Tokyo (JP)

Correspondence Address: COHEN, PONTANI, LIEBERMAN & PAVANE LLP, 551 FIFTH AVENUE, SUITE 1210, NEW YORK, NY, 10176, US

(21) Appl. No.: 12/664,880

(22) PCT Filed: Jun. 24, 2008
(86) PCT No.: PCT/JP2008/061450

§ 371 Date: Dec. 15, 2009

(30) Foreign Application Priority Data
Jul. 9, 2007 (JP) 2007-179529

(51) Int. Cl. H04N 5/225; H01L 31/0232; H01L 21/78

(52) U.S. Cl. 348/340; 438/65; 438/68; 348/E05.024; 257/E21.599; 257/E31.097; 257/E31.127

(57) ABSTRACT

Provided is an imaging device manufacturing method, which has the step of forming a plurality of imaging elements on one surface of a silicon wafer, the step of sealing a light receiving pixel portion for each imaging element by an imaging optical system, the step of cutting the silicon wafer into the individual imaging elements, the step of placing the cut imaging elements on a substrate, the step of connecting the substrate and the imaging elements electrically, the step of molding the substrate, the imaging optical system and the imaging elements integrally by a mold having identification marks with respect to each imaging element, and the step of cutting and separating the molded substrate into each every imaging element.

### TECHNICAL FIELD

The present invention relates to a manufacturing method of an imaging device having an imaging optical system to lead object light and an imaging element to perform photoelectric conversion of the object light led by the imaging optical system, an imaging device and a portable terminal provided with the imaging device.

### BACKGROUND

A compact and thin imaging device has been installed in a portable terminal represented by a compact and thin electronic device such as a mobile phone and a PDA (Personal digital Assistant), as a result, transmission of sound data as well as image data to a remote area has became possible.

As the manufacturing method of the above compact imaging device, there is known a method where a plurality of image sensors are formed on a silicon wafer in an array, a lens array where a plurality of optical lenses are formed is adhered on the silicon wafer and the silicon wafer is divided in accordance with the arrangement of the image sensors (for example. Patent Document 1: Unexamined Japanese Patent Application Publication No. 2002-290842).

On the other hand, conventionally, in order to identify semiconductor devices, there have been known a method to apply solder resist and print on the solder resist (for example, Patent Document 2: Unexamined Japanese Patent Application Publication No. 2000-332376), and a method that an stamping area is formed at an inner lead or a tub of an IC package sealed by a transparent resin and a mark is stamped there (for example, Patent Document 3: Unexamined Japanese Patent Application Publication No. 2001-127236).
Patent Document 1: Unexamined Japanese Patent Application Publication No. 2002-290842).
Patent Document 2: Unexamined Japanese Patent Application Publication No. 2000-332376).
Patent Document 3: Unexamined Japanese Patent Application Publication No. 2001-127236).

### DISCLOSURE OF THE INVENTION

### Problems to be Resolve by the Invention

However, in the manufacturing method of the Patent Document 1, the lens array is adhered so as to correspond to individuals of the plurality of the image sensors on the silicon wafer, thereafter the wafer is cut. Thus there is a problem that the wafer is divided into very small image sensors and orientation of each image sensor is not easily identified.

On the other hand, printing in a post-processing for identification such as the above Patent Document 2 requires a new process which creates a problem of cost increase. Also, in case of the imaging device, since it is covered by a member having light shielding characteristic, marking inside marks no sense.

The present invention has one aspect to solve the above problems and an object of the present invention is to provide a manufacturing method of the imaging device which enables to facilitate identification of orientation of the image sensors after separating when the plurality of imaging devices are formed integrally and cut into the individual imaging devices, and can identify at which position the imaging device was formed when it is formed integrally, as well as an imaging device.

### Means to Resolve the Problems

The above problems are solved by the following items.
1) A manufacturing method of an imaging device having an imaging optical system configured with an optical member, an imaging element to perform photoelectric conversion of object light led by the imaging optical system in which a plurality of light receiving pixel sections are formed having steps of:

forming a plurality of the imaging elements on one surface of a silicon wafer;

sealing the light receiving pixel sections with respect to each imaging element by the imaging optical system;

cutting the silicon wafer into each imaging element;

placing the plurality of the imaging elements having been cut on a substrate;

connecting the plurality of the imaging elements with the substrate electrically;

molding the substrate, the imaging optical system and imaging element integrally by a metal mold at which identification marks are formed with respect to each of the plurality of the imaging elements; and

cutting the molded substrate into each of the imaging elements to separate.
2) The manufacturing method of the imaging device of item 1, wherein the imaging optical system installed in the molding step is a single lens and a plurality of the single lenses connected by arm sections are installed.
3) A manufacturing method of an imaging device having an imaging optical system to lead object light and an imaging element to perform photoelectric conversion of the object light led by the imaging optical system in which a plurality of light receiving pixel sections are formed having steps of:

forming a plurality of the imaging elements on one surface of a silicon wafer;

sealing the light receiving pixel sections with respect to each imaging element by an optical member nearest to an image surface side to configure the imaging optical system;

cutting the silicon wafer into each of the imaging elements;

placing the plurality of the imaging elements having been cut on a substrate;

connecting the plurality of the imaging elements with the substrate electrically;

molding the substrate, the optical member nearest to the image surface side to configure the imaging optical system and the imaging element integrally by an metal mold at which identification marks are formed with respect to each of the plurality of the imaging elements;

installing other optical member to configure the imaging optical system; and

cutting the molded substrate into each of the imaging elements to separate.
4) A manufacturing method of an imaging device having an imaging optical system to lead object light and an imaging element to perform photoelectric conversion of the object light led by the imaging optical system in which a plurality of light receiving pixel sections are formed having steps of:

forming a plurality of the imaging elements on one surface of a silicon wafer;

sealing the light receiving pixel sections with respect to each imaging element by an optical member nearest to an image surface side to configure the imaging optical system;

cutting the silicon wafer into each imaging element;

placing the plurality of the imaging elements having been cut on a substrate;

connecting the plurality of the imaging elements with the substrate electrically;

molding the substrate, a part of the optical member to configure the imaging optical system and the imaging element integrally;

installing other optical member to configure the imaging optical system and a light shielding member unit at which identification marks with respect to each of the plurality of the imaging elements and

cutting the molded substrate into each of the imaging elements to separate.
5) The manufacturing method of the imaging device of item 4, wherein the other optical member to configure the imaging optical system and the light shielding member unit at which the identification marks with respect to each of the plurality of the imaging elements are formed integrally in advance.
6) The manufacturing method of the imaging device of any one of items 1 to 5, wherein the identification mark indicates at least a position of a reference pin of the imaging element or a position of the imaging element on the substrate.
7) The manufacturing method of the imaging device of any one of item 3 to 6, wherein a plurality of the optical members to be installed in the molding step are connected by the arm sections.
8) The manufacturing method of the imaging device of any one of items 3 to 7, wherein a plurality of the optical members to be installed after the molding step are connected by the arm sections.
9) The manufacturing method of the imaging device of item 8, wherein the arm sections to connect the optical members to be installed after molding step have flexibility.
10) An imaging device manufactured by the manufacturing method of the imaging device of any one of items 1 to 9.
11) A mobile phone comprising the imaging device of item 10.

### Effect of the Invention

According to the present embodiment, there are provided an imaging device manufacturing method which facilitates identification of orientation of the image sensors after separating when the plurality of the imaging devices are formed integrally and cut into the individual imaging devices and enables to identify at which position the imaging device was formed when it is formed integrally, as well as an imaging device.

### BRIEF DESCRIPTION OF THE DRAWINGS

FIGS. 1(a), (b) and (c) are frame formats showing process steps in an initial stage of a manufacturing method of an imaging device related to a first embodiment.

FIGS. 2(a), (b) (c) and (d) are frame formats showing process steps in a later stage of a manufacturing method of an imaging device related to a first embodiment.

FIG. 3 is views showing other example of identification marks formed on each imaging device.

FIGS. 4(a), (b), (c) and (d) are frame formats showing process steps in an initial stage of a manufacturing method of an imaging device related to a second embodiment.

FIGS. 5(a), (b) and (c) are frame formats showing process steps in a middle stage of a manufacturing method of an imaging device related to a second embodiment.

FIGS. 6(a) and (b) are frame formats showing process steps in a later stage of a manufacturing method of an imaging device related to a second embodiment.

FIGS. 7(a) and (b) are frame formats showing process steps in a later stage of a manufacturing method of an imaging device related to a third embodiment.

FIGS. 8(a) and (b) are views showing an example where a lens group integral unit and a light shielding member unit are formed integrally in advance.

FIG. 9 is external views of a mobile phone representing an example of a portable terminal provided with an imaging device related to the present embodiment.

FIG. 10 is a block diagram of control of a mobile phone.

### DESCRIPTION OF SYMBOLS

11 Silicon wafer

12 Imaging element

13 Adhesive

14 Optical member

19 Dicing blade

21 Substrate

25 Identification mark

30 Lens group integral unit

31 Lens

32 Light shielding member unit

50 Imaging device

100 Mobile phone

MD Molding

YB Wire bonding

### DESCRIPTION OF THE PREFERRED EMBODIMENTS

Embodiments of the present invention will be described specifically as follow without the present invention being limited to the embodiments thereof.

### First Embodiment

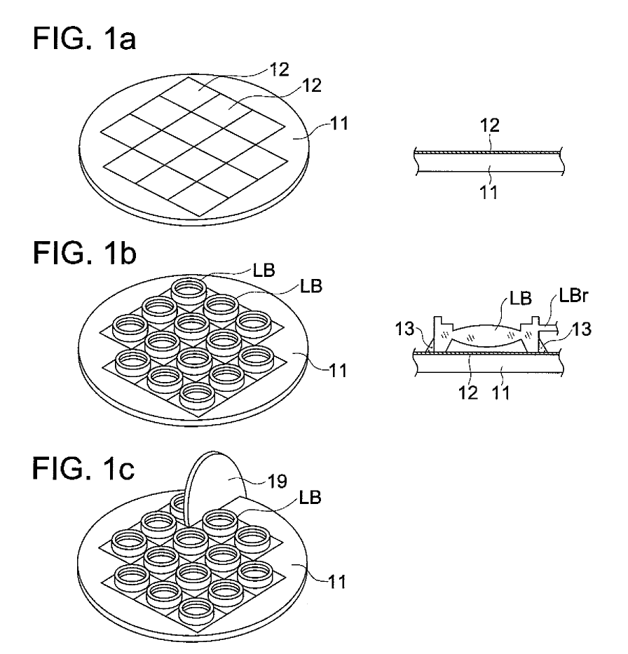

FIGS. 1(a), (b) and (c) are frame formats showing process steps in an initial stage of a manufacturing method of an imaging device related to a first embodiment. The figures on the left hand side schematically show total appearances and the figures on the right hand side schematically show cross-sectional views of individuals in the total appearance thereof.

First, a plurality of imaging elements 12 are formed on one surface of a silicon wafer 11 shown by FIG. 1(a). In the above process, a publicly known film forming process, a photolithography process, an etching process, an impurity addition process are repeated so as to from transfer electrodes, isolation films and wiring in a multiplayer structure and the plurality of the imaging elements 12 are formed in an array form. The aforesaid imaging elements 12 are the image sensors such as, for example, CCD (Charged Coupled Device) type image sensors and CMOS (Complementary Metal-Oxide Semiconductor) type image sensors.

Next, as the FIG. 1(b) shows, single lenses LB representing an imaging optical system are placed and fixed respectively corresponding to the plurality of the imaging elements 12 formed on the silicon wafer 11. Since the plurality of the single lenses LB are connected at connection sections LBr, the single lenses LB are collectively placed on the individual imaging elements 12 and fixed by an adhesive. In the above way, while it is preferable that processes to install the lens LB can be reduced and the cost is reduced, there can be a configuration that the lens LB is a single piece and installed individually. Incidentally, the infrared ray protection coating is applied to the lens LB.

Next, as FIG. 1(c) shows, the silicon wafer 11 is cut by a dicing saw blade 19 into individual imaging elements. Whereby, a light receiving element area is sealed by the lens LB and individual chips of the imaging element 12 chips are produced.

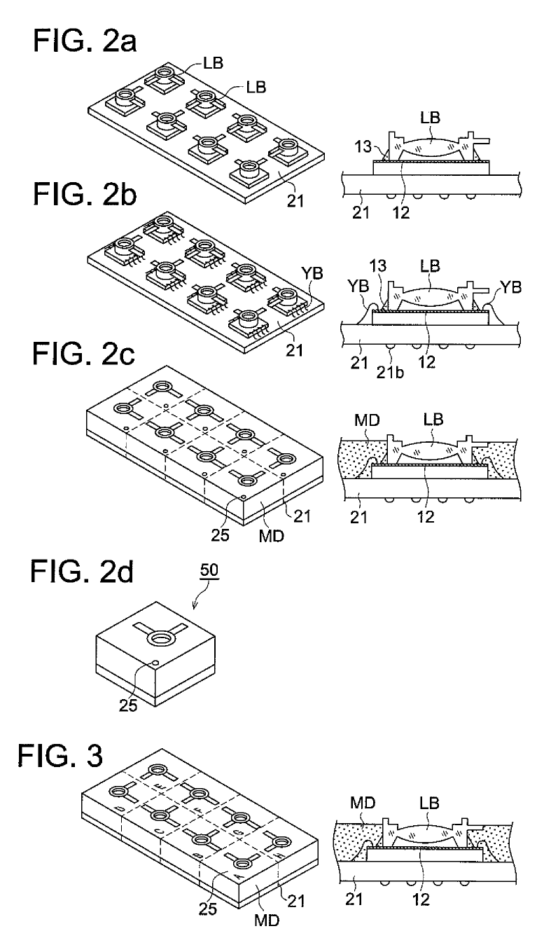

FIGS. 2(a), (b) (c) and (d) are frame formats showing process steps in a later stage of a manufacturing method of an imaging device related to a first embodiment.

As FIG. 2(a) shows, the plurality of the chips of the imaging elements 12 where the lenses LB are adhered are placed on the substrate 21 chip. In the substrate 12, a plurality of wires corresponding to individual chips of the imaging elements 12 are formed so that the plurality of the chips of the imaging elements 12 can be placed.

Incidentally, the chips of the imaging elements 12 to be placed are only the chips of the imaging elements 12 which are judged to be conforming chips through an inspection. Whereby wasting of parts such as the lenses to be installed afterward can be saved.

Next, as FIG. 2(b) shows, the chip of the imaging element 12 and the substrate 21 are electrically connected through wire bonding YB. On the other surface of the substrate 21, a plurality of external electrodes 21b (for example, solder ball) used for connecting with an unillustrated other control substrate are formed. Whereby, the input and output of signals between the unillustrated other control substrate to be connected to the substrate 21 and the imaging element 12 are possible.

After that, as FIG. 2(c) shows, a resin material MD is injected onto an imaging element 12 side surface of the substrate 21, and as the figure shows, the surface is molded integrally in a way that only the lens LB nearest to an object at an object side of the imaging optical system is exposed. Whereby, in the example shown in the figure, eight units of imaging devices are integrally formed.

When this occurs, at the metal mold used in molding, an identification mark 25 to show a position of a reference pin among terminals of the imaging element is formed in respect to each image element. As the figure shows, on outer surfaces of the plurality of the imaging devices formed integrally, the identification marks 25 to show the individual positions of the reference pins are formed. The identification mark can be in a shape of a projection or a recess.

After that, the silicon wafer is cut along a broken lines shown in the FIG. 2(c), and individual image devices shown in FIG. 2(d) are completed. As FIG. 2(d) shows, the identification mark 25 to show the position of the reference pin among the terminals of the imaging element is indicated on each imaging device so that mis-installation of the imaging device onto unillustrated equipment.

Incidentally, in the above description, while the imaging optical system has a single lens, an imaging optical system wherein a plurality of lenses are integrated by an adhesive is possible.

FIG. 3 is views showing other example of identification mark formed on each imaging device.

The identification mark 25 shown in FIG. 3 denoted by alphabet indicates the reference pin position among the terminals on the imaging element by its position and indicates at which position each imaging device located when the plurality of the imaging devices were integrally formed.

As above, using alphabet or numeral as the identification mark, the positions when the individual imaging devices were integrally formed can be identified.

### Second Embodiment

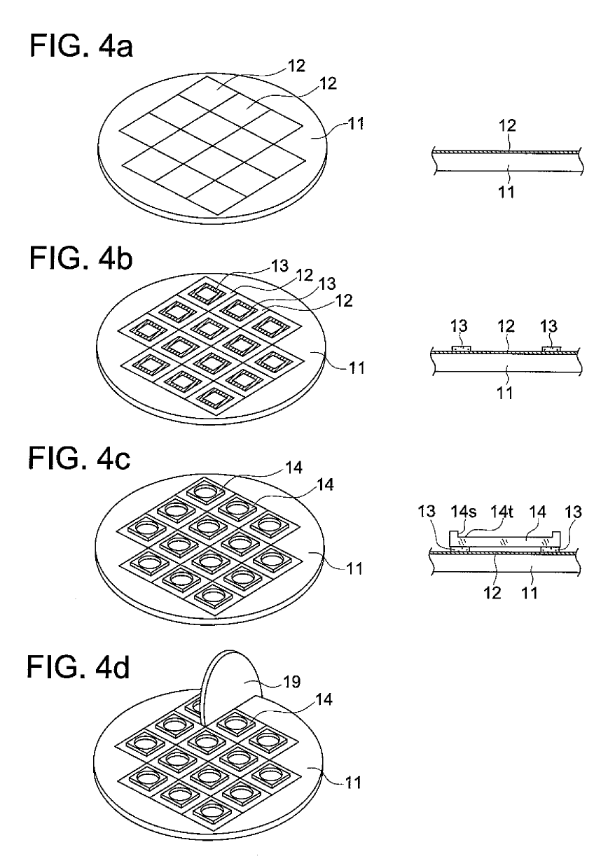

FIGS. 4(a), (b), (c) and (d) are frame formats showing process steps in an initial stage of a manufacturing method of an imaging device related to a second embodiment. The figures on the left hand side schematically show total appearances and the figures on the right hand side are cross-sectional views showing individuals in the total appearances thereof.

First, a plurality of the imaging elements 12 are formed on one surface of the silicon water 11 shown by FIG. 4(a).

Next, as FIG. 4(b) shows, an adhesive 13 is applied to a plurality of individual imaging elements 12 formed on the silicon wafer 11. The adhesive is applied at a position keeping away from a light receiving pixel area. Also, by adjusting an amount of the adhesive, a distance between an imaging surface and the optical member to be adhered above the light receiving pixel area is determined.

After that, as FIG. 4(c) shows, the optical member 14 configuring the image optical system nearest to an object at an object side is adhered. By adhering the optical member 14, the light receiving pixel area of the imaging element 12 is sealed. In the present example, an area of the optical member 14 which locates above the light receiving pixel area of the imaging element 12, namely an area through which the object light passes, is formed to be a parallel plane. In an area where the object light does not pass through, a positioning section to position the lens to be installed later is formed. The positioning section is represented by a recessed surface in a shape of a circle and a wall surface section 14s in the present example. Incidentally, an infrared ray protection coating is applied to the optical member 14.

Next, as FIG. 4(d) shows, the silicon wafer 11 is cut by the dicing saw blade 19 into each imaging element. Whereby the individual chips of the imaging elements 12, wherein the light receiving pixel area is sealed by the optical member 14, are formed.

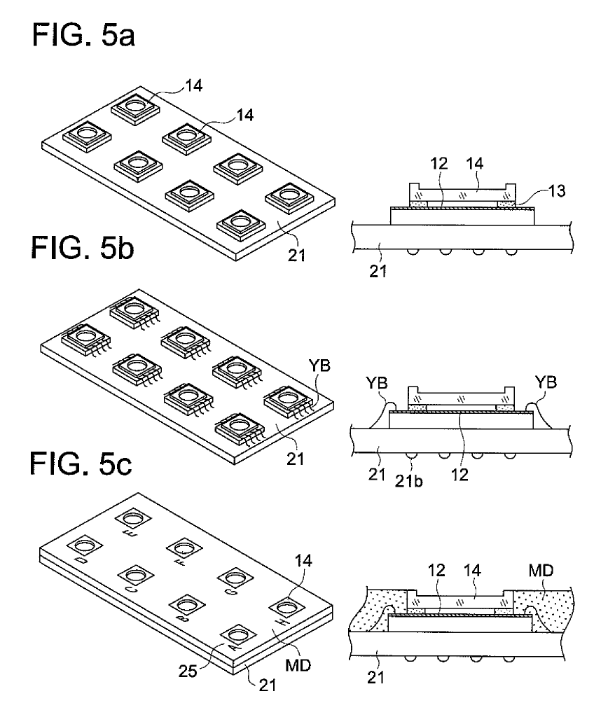

FIGS. 5(a), (b) and (c) are frame formats showing process steps in a middle stage of a manufacturing method of an imaging device related to a second embodiment.

The plurality of the chips of the individual imaging elements 12 to which the optical members 14 are adhered are placed on the substrate 21. On the substrate 21, a plurality of wires corresponding to the chips of the individual imaging elements 12 are formed so that the plurality of the imaging elements can be placed.

Incidentally, the chips of the imaging elements 12 to be placed are only the chips of the imaging elements 12 which are judged to be conforming chips through an inspection. Whereby wasting of parts such as lenses to be installed afterward can be saved.

Next, as FIG. 5(b) shows, the chip of the imaging element 12 and the substrate 21 are electrically connected through wire bonding YB. On the other surface of the substrate 21, a plurality of external electrodes 21b (for example, solder ball) used for connecting with an unillustrated other control substrate are formed. Whereby, the input and output of signals between the unillustrated other control substrate to be connected to the substrate 21 and the imaging element 12 are possible.

After that, as FIG. 5(c) shows, a resin material MD is injected onto an imaging element 12 side surface of the substrate 21 so as to integrally mold the substrate 21 in a way that only the optical member 14 is exposed. When this occurs, on the metal mold used in molding, an alphabetic identification mark 25 to show a position of a reference pin among terminals of the imaging element with respect to each imaging element and to show at which position the individual imaging elements were formed. Thus as the figure shows, on outer surfaces of the plurality of the imaging devices formed integrally, the identification marks 25 are formed. The identification mark can be numeral in a shape of a projection or a recess.

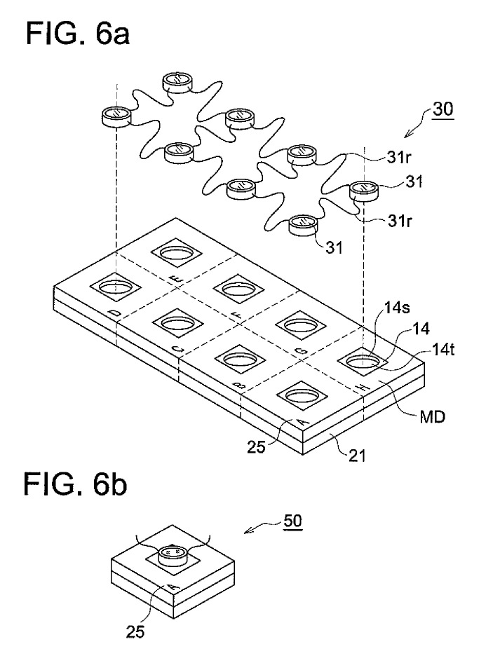

FIGS. 6(a) and (b) are frame formats showing process steps in a later stage of a manufacturing method of an imaging device related to a second embodiment.

As FIG. 6(a) shows, a lens 31 representing the other optical member to configure the imaging optical system is installed in a state where the plurality of the chips of the imaging elements 12 are integrally molded. The imaging optical system is a lens group integral unit where a plurality of the lenses 31 are connected through flexible arm sections 31r and formed integrally. Each lens 31 fits an exposing wall surface 14s of the optical member 14 while each lens 31 is being connected through the arm sections 31r so as to determine a position in a direction orthogonal to a light axis. Also, the lens 31 comes in contact with the recessed surface 14t so as to determine a position in a light axis direction and is installed, and then fixed by the adhesive (Refer to FIG. 4(c)).

Whereby, eight units of imaging devices shown in the FIG. 4(c) are formed integrally. Incidentally, while it is preferable costwise that the positioning and assembling is carried out while being connected through the flexible arm section 31r, the lens 31 can be a single lens and assembled individually.

Thereafter, by cutting the wafer at broken lines shown in FIG. 6(a) to separate, individual imaging devices 50 shown by FIG. 6(b) are separated and completed.

By the above manner, the position of the identification mark 25 indicates the position of the reference pin among the terminals of the imaging element, also indicates at which position the individual imaging devices were located when the plurality of the imaging devices were integrally formed. Whereby mis-installation of the imaging elements in an unillustrated equipment can be avoided.

Further, by always installing each lens 31 of the lens group integrated unit 30 at a position corresponding to the same identification mark, for example, in case the lens 31 at a specific position is defective due to a problem of the metal mold among the lens group integral unit, judgment is possible even after the imaging element in which the lens has been installed is cut to be separated.

Meanwhile, the examples where the infrared ray protection coating is applied to the optical member 14 have been described without being limited to the coating thereof. The lens 31 applied by infrared ray protection coating or a separate infrared ray protection filter can be installed.

Also, the examples using the optical member, wherein the positioning member is formed in the area through which the object light does not pass and the area through which the object light passes is formed to be the parallel plane have been described. The optical member and the lens entirely configured with the parallel plane are possible.

### Third Embodiment

The manufacturing method of the third embodiment is the same as that of the second embodiment at the process steps in the initial and middle stage. Thus only the process step in the later stage will be described.

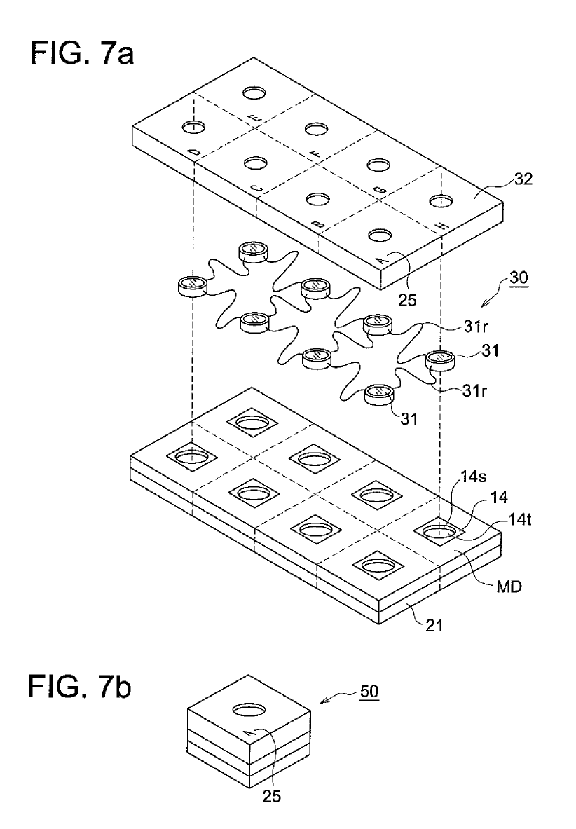

FIGS. 7(a) and (b) are frame formats showing process steps in a later stage of a manufacturing method of an imaging device related to a third embodiment.

After process steps of the initial stage and the middle stage shown by FIGS. 4 and 5, the lens 31 configuring the imaging optical system and the light shielding member unit 32 are assembled in a state where the plurality of the imaging elements 12 are molded integrally. The imaging optical system is a lens group integral unit 30 where the plurality of the lens 31 connected with the flexible arms 31r and formed integrally. The individual lenses 31 are positioned in a direction orthogonal to the light axis by fitting with an exposed wall surface 14s of the optical member 14 while maintaining a state where the lenses are connected with the flexible arm sections 31r. Also, the lenses come to contact with the recessed surface 14t so that the positioned of the lens is determined in the light axis direction so as to be installed (FIG. 4(c)). Next, the light shielding member units 32 are overlapped so that the lens 31 is interposed between them and fixed. The light shielding member units 32 are stacked so that the lens 31 is covered and fixed. A plurality of the light shielding member units 32 are integrally formed in the same manner. Thus, eight units of imaging devices are integrally formed in the example shown in the figure.

Incidentally, as FIG. 7 show, on the light shielding member unit 32, a plurality of the identification marks 25 are formed with respect to individual imaging elements. It is preferred that each light shielding member unit 32 is always installed at a position to correspond the same identification mark.

After that, by cutting the wafer alone the broken lines shown in FIG. 7(a) the imaging devices 50 are separated into single products and completed as FIG. 7(b) shows.

Incidentally, the light shielding member unit 32 is not limited to the resin mold product, it can be a metal member formed by etching and so forth. Also, it can be used by stacking a plurality of the shields. Meanwhile, it is preferred that the lens and the light shielding member unit are installed while being connected with the flexible arm sections 31r costwise, however individual lens 31 and the light shielding member unit 32 can be installed separately.

As above, the position of the identification mark 25 shows the position of the reference pin among the terminals of the imaging element, also shows at which position each imaging device has been located when the plurality of the imaging devices are formed integrally. Thus mis-installation of the imaging device into an unillustrated equipment is avoided.

Further, by always installing each lens 31 of the lens group integral unit 30 at the position which corresponds to the same identification mark, for example, in case the lens 31 at a specific position is defective due to a problem of the metal mold among the lens group integral unit 30, the defective lens can be identified even after the imaging devices in which the lenses are installed are separated.

Incidentally, while the examples in which the optical member 14 is coated with infrared ray protection coating have been described without being limited to the coated optical member thereof, the lens 31 coated with infrared ray protection coat or a separate infrared ray protection filter can be installed.

Also, the examples using the optical member, wherein the positioning member is formed in the area through which the object light does not pass and the area through which the object light passes is formed to be the parallel plane have been described. The optical member entirely configured with the parallel plane are possible.

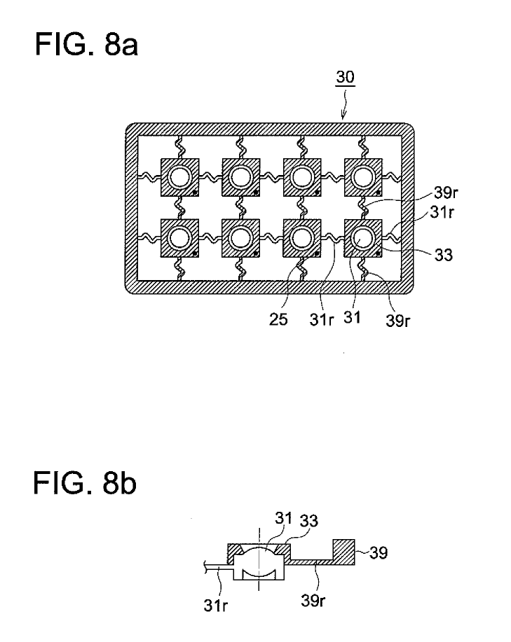

FIGS. 8(a) and (b) are views showing an example where a lens grope integral unit and a light shielding member unit are formed integrally in advance. FIG. 8(a) is a plane view and FIG. 8(b) is a partial cross-sectional view.

In the lens group integral unit 30 and the light shielding member unit 32, shown in FIG. 8, the light shielding section 33 formed with the resin having a light shielding characteristic and the lens section 31 formed with the resin having a transparency are formed through two color molding.

In the lens group integral unit 30 shown in FIGS. 8(a) and (b), two are section 39r and one light shielding section 33 formed with the resin having light shielding characteristic are formed with respect to each lens 31, and the lens 31 and the arm section 31r are formed with a resin having transparency and then both are formed through two color molding. The identification marks 25 are formed on an outer surface of a shielding section 33.

The above configuration can be formed as follow. Two arm sections and the light shielding section 33 are molded in advance with the resin having light shielding characteristic by the first metal mold, then the product molded with the resin having light shielding characteristic is inserted in the second metal mold, and then the lens 31 and two arm sections 31r are molded by the second metal mold with the resin having transparency, in addition to the two arm sections and the shielding section 33 having the light shielding characteristic in the second metal mold.

As above, the lens and the shielding member unit on which the identification mark for each imaging element are formed integrally in advance and then installation can be carried out after the plurality of the chips of the imaging elements 12 are molded integrally.

Incidentally, in the above first to third embodiments, the examples where eight imaging devices integrally formed and separated have been described, however the number of the products molded integrally is obviously not limited to eight.

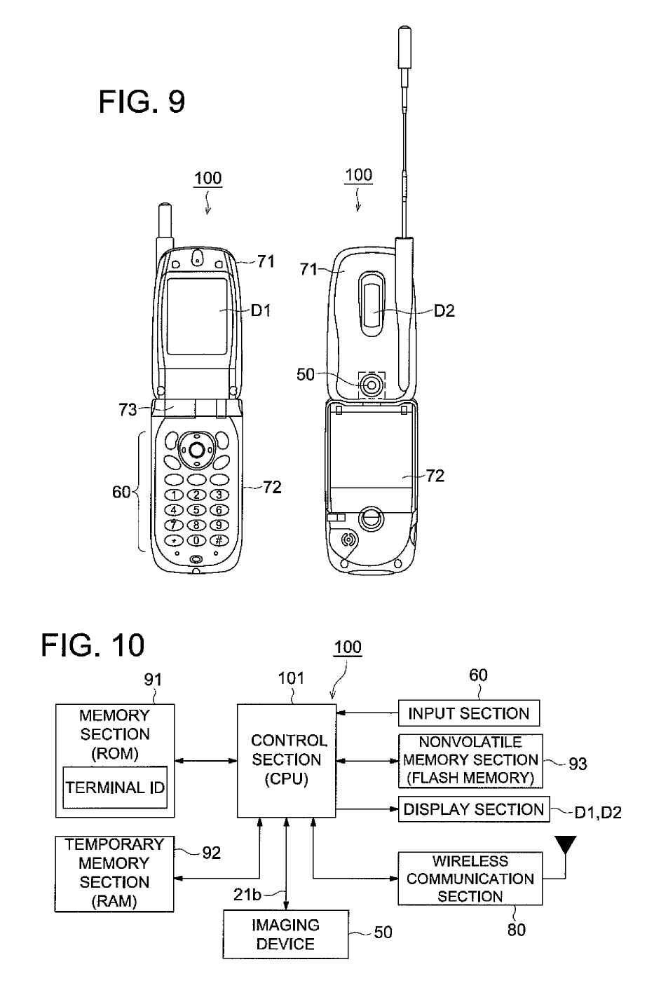

FIG. 9 shows external views of a mobile phone 100 representing an example of a portable terminal provided with an imaging device 50 related to the present embodiment.

In the mobile phone 100 shown in FIG. 9, an upper housing representing a case provided with a display screens D1 and D2 and a lower housing 72 provided with operation buttons 60 representing an input section are connected with a hinge 73. The imaging device 50 is installed under the display screen D2 in the upper housing 71 so that the imaging device can capture light from an outer surface side of the upper housing 71.

Meanwhile, the imaging device can be located above or a side surface of the display screen D2 in the upper housing. Also, the mobile phone is obviously not limited to a folding type.

FIG. 10 is a block diagram of control of a mobile phone 100.

As FIG. 10 shows, the imaging device 50 is connected with the control section 101 of the mobile phone 100 via external electrode 21b of the imaging device 50 so as to output image signals such as a brightness signal and a color-difference signal to the control section 101.

On the other hand, the mobile phone 100 controls each section overall and is provided with the control section (CPU) 101 to execute programs in accordance with each process, the operation buttons 60 representing the input section to instruct and input telephone numbers, the display screens D1 and D2 to display predetermined data and photographed images, a wireless communication section 80 to realize various information communication with an external server, a memory section (ROM) 91 to store a system program of the mobile phone 100, various processing programs and necessary data such as terminal ID, temporary memory (RAM) 92 to temporarily store programs and data executed by the control section 101, processed data and image data captured by the imaging device 50 or to be used as a work area.

Also, the image signal inputted from the imaging device 50 is stored in a nonvolatile memory section (flush memory) 93 via control section 101 of the mobile phone 100, displayed on the display screens D1 and D2 or outputted to an outside as image information via the wireless communication section 80.

1. A manufacturing method of an imaging device having an imaging optical system configured with an optical member, an imaging element to perform photoelectric conversion of object light led by the imaging optical system in which a plurality of light receiving pixel sections are formed comprising steps of:
forming a plurality of the imaging elements on one surface of a silicon wafer;
sealing the light receiving pixel sections with respect to each imaging element by the imaging optical system;
cutting the silicon wafer into each imaging element;
placing the plurality of the imaging elements having been cut on a substrate;
connecting the plurality of the imaging elements with the substrate electrically;
molding the substrate, the imaging optical system and imaging element integrally by a metal mold at which identification marks are formed with respect to each of the plurality of the imaging elements; and
cutting the molded substrate into each of the imaging elements to separate.

2. The manufacturing method of the imaging device of claim 1, wherein the imaging optical system installed in the molding step is a single lens and a plurality of the single lenses connected by arm sections are installed.

3. A manufacturing method of an imaging device having an imaging optical system to lead object light and an imaging element to perform photoelectric conversion of the object light led by the imaging optical system in which a plurality of light receiving pixel sections are formed comprising steps of:
forming a plurality of the imaging elements on one surface of a silicon wafer;
sealing the light receiving pixel sections with respect to each imaging element by an optical member nearest to an image surface side to configure the imaging optical system;
cutting the silicon wafer into each of the imaging elements;
placing the plurality of the imaging elements having been cut on a substrate;
connecting the plurality of the imaging elements with the substrate electrically;
molding the substrate, the optical member nearest to the image surface side to configure the imaging optical system and the imaging element integrally by an metal mold at which identification marks are formed with respect to each of the plurality of the imaging elements;
installing other optical member to configure the imaging optical system; and
cutting the molded substrate into each of the imaging elements to separate.

4. A manufacturing method of an imaging device having an imaging optical system to lead object light and an imaging element to perform photoelectric conversion of the object light led by the imaging optical system in which a plurality of light receiving pixel sections are formed comprising steps of:
forming a plurality of the imaging elements on one surface of a silicon wafer;
sealing the light receiving pixel sections with respect to each imaging element by an optical member nearest to an image surface side to configure the imaging optical system;
cutting the silicon wafer into each imaging element;
placing the plurality of the imaging elements having been cut on a substrate;
connecting the plurality of the imaging elements with the substrate electrically;
molding the substrate, a part of the optical member to configure the imaging optical system and the imaging element integrally;
installing other optical member to configure the imaging optical system and a light shielding member unit at which identification marks with respect to each of the plurality of the imaging elements and
cutting the molded substrate into each of the imaging elements to separate.

5. The manufacturing method of the imaging device of claim 4, wherein the other optical member to configure the imaging optical system and the light shielding member unit at which the identification marks with respect to each of the plurality of the imaging elements are formed integrally in advance.

6. The manufacturing method of the imaging device of claim 1, wherein the identification mark indicates at least a position of a reference pin of the imaging element or a position of the imaging element on the substrate.

7. The manufacturing method of the imaging device of claim 3, wherein a plurality of the optical members to be installed in the molding step are connected by the arm sections.

8. The manufacturing method of the imaging device of claim 3, wherein a plurality of the optical members to be installed after the molding step are connected by the arm sections.

9. The manufacturing method of the imaging device of claim 8, wherein the arm sections to connect the optical members to be installed after molding step have flexibility.

10. An imaging device manufactured by the manufacturing method of the imaging device of claim 1.

11. A mobile terminal comprising the imaging device of claim 10.
